(19) United States
(12) Patent Application Publication
(10) Pub. No.: US 2009/0302421 A1
(43) Pub. Date: Dec. 10, 2009

(54) Method and apparatus for creating a deep trench capacitor to improve device performance

(75) Inventors: Charu Sardana, San Jose, CA (US); Bradley Jensen, San Jose, CA (US); Irfan Rahim, Milpitas, CA (US); Jeffrey T. Watt, Palo Alto, CA (US)

Correspondence Address: LAWRENCE M. CHO, P. O. BOX 2144, CHAMPAIGN, IL, 61825, US

(73) Assignee: Altera Corporation

(21) Appl. No.: 12/157,211

(22) Filed: Jun. 9, 2008

(51) Int. Cl. H01L 29/00; H01L 21/20

(52) U.S. Cl. 257/532; 438/386; 257/E21.09; 257/E29.001

(57) ABSTRACT

A deep trench capacitor includes a trench having walls and a floor. The deep trench capacitor also includes a layer of gate oxide on the walls and floor. Gate polysilicon is deposited over the gate oxide.

### TECHNICAL FIELD

Embodiments of the present invention relate to submicron devices such as complementary metal oxide semiconductor (CMOS) devices on target devices. More specifically, embodiments of the present invention relate to a method and apparatus for creating a deep trench capacitor to improve device performance.

### BACKGROUND

A number of design issues exist when designing target devices. For example, when adjacent P-wells on a semiconductor substrate are biased at different voltages, the P-wells need to be isolated. Without isolation, a current path may form between the P-wells.

Traditionally, a P-well biased at a first voltage may be isolated from a P-well biased at a second voltage by forming a N-well between them and a deep N-well below them. In order to be effective, however, the width of the N-well must typically be at least 1 μm. The width requirement for N-well isolation impacted the scalability of transistors on the semiconductor substrate.

Another design issue that exists when designing a target device is making the target device less susceptible to soft errors. Soft errors occur when cosmic rays directly or indirectly generate electron hole pairs and produce an ionized path. For example, a 5 MeV alpha particle can produce more than 200 femtocoulombs of hazardous electrons. Memories that store a charge at V_{cc} may experience a drop and may flip from a 1 to a 0 resulting in a soft error.

In order to prevent the effects of cosmic rays, nodes in the memories have been designed to have a higher capacitance. By increasing the capacitance at a node, a higher charge is required before a soft error occurs and protection is provided. Traditionally, this would involve making the memories larger which also impacted the scalability of the memories.

### SUMMARY

According to an embodiment of the present invention, a deep trench capacitor is formed to reduce soft errors. The deep trench capacitor is formed using one or more existing procedures used for creating transistors on the semiconductor substrate. These procedures may include depositing gate oxide, polysilicon, and/or silicide. By utilizing existing procedures to form the deep trench capacitor, a separate module is not required for the deep trench process and resources such as timing and costs are reduced. According to one aspect of the present invention, the deep trench capacitor may be constructed around a well doped with a first type of dopant to also provide isolation of the well.

### BRIEF DESCRIPTION OF THE DRAWINGS

The features and advantages of the present invention are illustrated by way of example and are by no means intended to limit the scope of the present invention to the particular embodiments shown.

FIG. 1 is a flow chart illustrating a method for fabricating a deep trench capacitor with a metal oxide semiconductor transistor according to an embodiment of the present invention.

FIG. 2 is a flow chart illustrating a method for fabricating a deep trench capacitor with a gate of a metal oxide semiconductor transistor according to an embodiment of the present invention.

FIGS. 3a-3f illustrate the formation of a deep trench capacitor according to an embodiment of the present invention.

FIG. 4 illustrates an embodiment of a deep trench capacitor that is configured for deep trench isolation according to an embodiment of the present invention.

FIG. 5 illustrates deep trench capacitors implemented in a circuit to reduce soft errors according to an embodiment of the present invention.

FIG. 6 illustrates a target device where deep trench capacitors are implemented according to embodiments of the present invention.

### DETAILED DESCRIPTION

In the following description, for purposes of explanation, specific nomenclature is set forth to provide a thorough understanding of embodiments of the present invention. It will be apparent to one skilled in the art that specific details in the description may not be required to practice the embodiments of the present invention. In other instances, well-known components, devices, materials and processes are shown in block diagram form to avoid obscuring embodiments of the present invention unnecessarily.

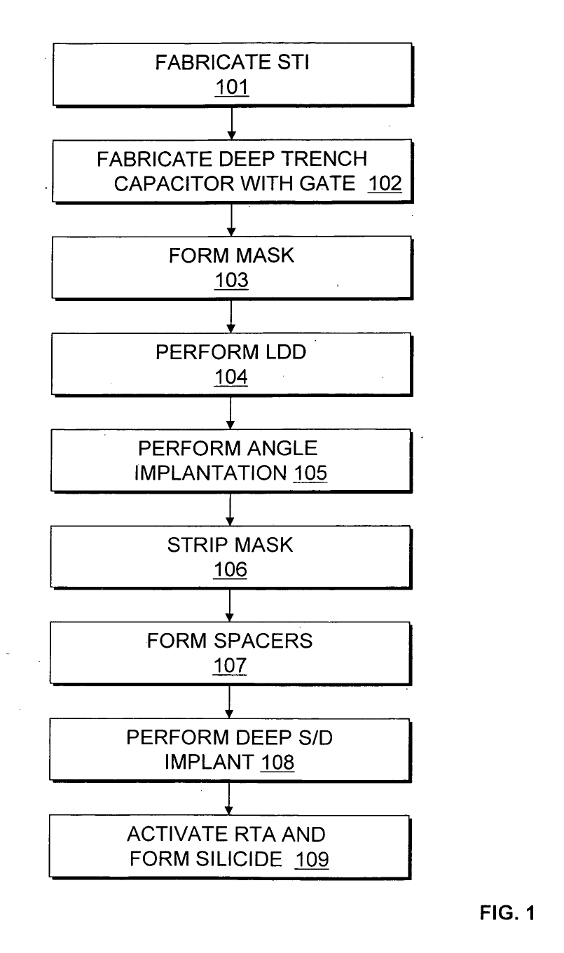

FIG. 1 is a flow chart illustrating a method for fabricating a deep trench capacitor with a metal oxide semiconductor transistor according to an embodiment of the present invention. At 101, shallow trench isolation is formed for the transistor. Shallow trench isolation is an integrated circuit feature which prevents electrical current leakage between adjacent semiconductor components, well areas doped with different dopant types, or well areas for transistors biased at different voltages.

According to an embodiment of the present invention, shallow trench isolation may be formed by applying a mask. A photolithography process may be used to cover areas on the silicon that are reserved for trenches with a photoresist material. It should be appreciated that either positive or negative photoresist may be used. The exposed areas of the silicon are etched to form trenches. The mask is removed and the exposed area is filled with a dielectric. According to an embodiment of the present invention, the exposed area is filled with silicon dioxide. Excess dielectric is polished off. According to an embodiment of the present invention, chemical-mechanical planarization or other techniques may be used to polish the dielectric.

At 102, the deep trench capacitor and the gate of the transistor are fabricated. The fabrication of the deep trench capacitor is performed together with the fabrication of the gate of the transistor. According to an embodiment of the present invention, the deep trench capacitor is formed using one or more existing procedures used for creating transistors on a semiconductor substrate. These procedures may include depositing gate oxide, gate polysilicon, and/or silicide. By utilizing existing procedures that would otherwise be necessary to form components of transistors, a separate module is not required to fabricate the deep trench process and resources such as timing and costs are reduced.

At 103, a mask is formed on the polysilicon. The mask is formed to block out dopants of a particular type (n-type or p-type dopants). According to an embodiment of the present invention, mask may be any type of blocking mask including photo resist or a hard mask formed from a material having a higher density than photoresist. Forming the hard mask includes depositing the mask and patterning the mask such that it covers a second region that includes a polysilicon well of a second dopant type while exposing a first region that includes a polysilicon well of the first dopant type.

At 104 lightly doped drain (LDD) implant is applied to the device. The LDD implant may be applied at zero-degrees. The exposed silicon may be doped with a high concentration of impurities, either though diffusion or ion implantation. The doping penetrates exposed areas on the silicon surface creating n-type or p-type regions (source and drain junctions) in a p-type or n-type substrate. After LDD implantation, the photoresist over the second region may be stripped. Alternatively, the photoresist may be removed prior to LDD implantation. According to an embodiment of the present invention, the photoresist over the second region may be stripped through a dry process or using a solvent.

At 105, angled implantation is performed of the first dopant type to form pockets under the gate of the second dopant type. According to an embodiment of the present invention, implantation may be performed at multiple angles to form shallow and deep pockets.

At 106, the hard mask is stripped.

Procedures 103-106 are specific in describing how a first transistor of the first dopant type is created in the first region. It should be appreciated that procedures 103-106 may be modified to create a second transistor of the second dopant type in the second region.

At 107, spacers are formed adjacent to the gate.

At 108, deep source drain (S/D) implant is performed. The deep source drain implants dopes the exposed silicon with a high concentration of impurities, either through diffusion or ion implantation. The doping further penetrates exposed areas on the silicon surface further defining the n-type or p-type regions (source and drain junctions) deeper in the p-type or n-type substrate. According to an embodiment of the present invention, the dose may be 1E14 to 1E15 Ion/cm².

At 109, rapid thermal annealing and silicide formation is performed. According to an embodiment of the present invention, rapid thermal annealing operates to activate dopants and to make them more conductive.

FIG. 1 illustrates several of the procedures performed in fabricating a deep trench capacitor with a metal oxide semiconductor transistor. It should be appreciated that other additional procedures may be performed before or after any of the procedures described. Such procedures may include the creation of wells, deep wells, and other components of the metal oxide semiconductor transistor.

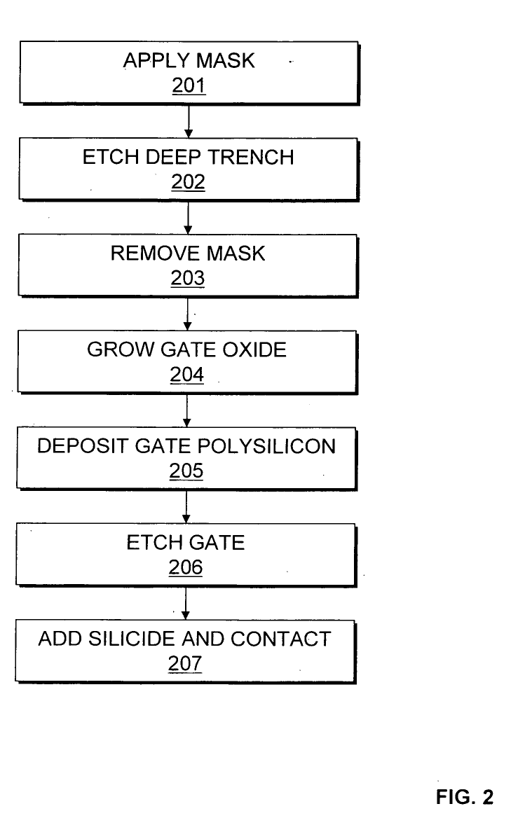

FIG. 2 is a flow chart illustrating a method for fabricating a deep trench capacitor with a gate of a metal oxide semiconductor transistor according to an embodiment of the present invention. The procedures illustrated in FIG. 2 may be used to implement 102 illustrated in FIG. 1. At 201, a mask is applied for deep trench isolation. A photolithography process may be used to expose areas on the silicon reserved for the deep trenches. Either positive or negative photoresist may be used. It should be appreciated that alternatively a hard mask may be used. According to an embodiment of the present invention, the hard mask is formed from a material having a higher density than photoresist. The material is one that may be planarized using a technique such as chemical-mechanical and polish procedure. Forming the hard mask may include depositing the hard mask on the polysilicon, planarizing the hard mask, and patterning the hard mask such that it includes openings exposed for regions designated for the deep trench capacitors. The hard mask may be formed using Si₃N₄ or other material.

At 202, the exposed areas of the silicon are etched to form deep trenches. According to an embodiment of the present invention, plasma ions are used to perform dry etching.

At 203, the mask is removed.

At 204, a gate oxide layer is grown in the deep trench formed at the same time that gate oxide layer for a gate on the transistor is grown. According to an embodiment of the present invention, the gate oxide is a thick input output (IO) oxide. The gate oxide layer may be used as the gate dielectric for the transistor. Excess gate oxide is cleaned up.

At 205, a layer of gate polysilicon (polycrystalline silicon) is deposited on top of the gate oxide for the transistor and the gate oxide for the deep trench capacitor. The gate polysilicon may be used as gate electrode material for the metal oxide semiconductor transistor.

At 206, the gate polysilicon layer and gate oxide layer are etched. The gate polysilicon layer may be patterned and etched to form the interconnects and the metal oxide semiconductor transistor gates. The gate oxide not covered by polysilicon may also be etched, away to expose the bare silicon on which source and drain junctions are to be formed.

At 207, silicide and a contact are added on the deep trench capacitor. According to an embodiment of the present invention, the layer of silicide and/or the contact may be added to the deep trench capacitor while silicide and/or contacts are added to transistors on the semiconductor substrate (such as at 108 described in FIG. 1). It should also be appreciated that the silicide and/or contact may be added separately at a different procedure.

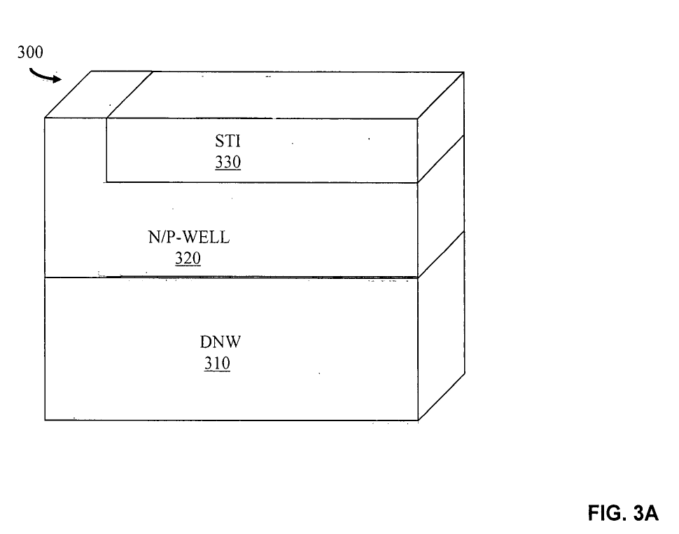

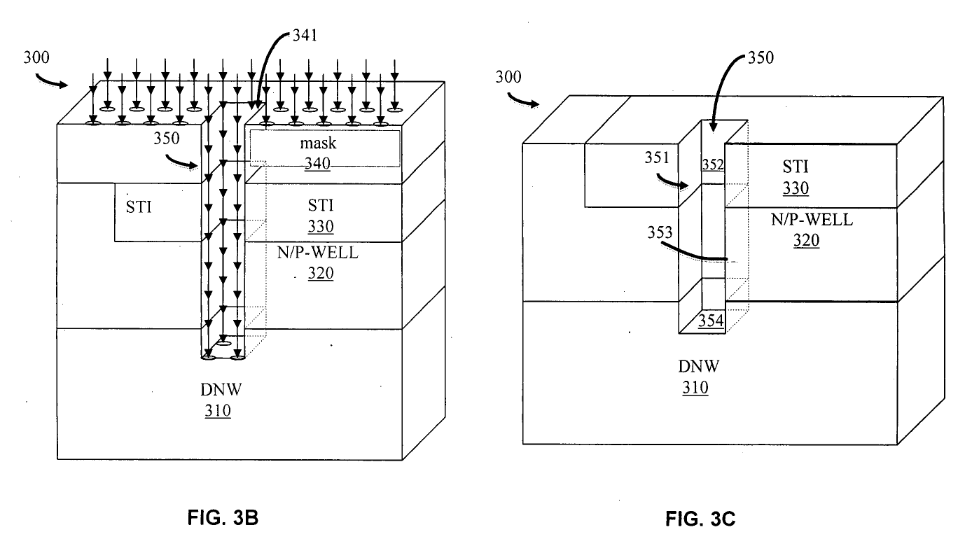

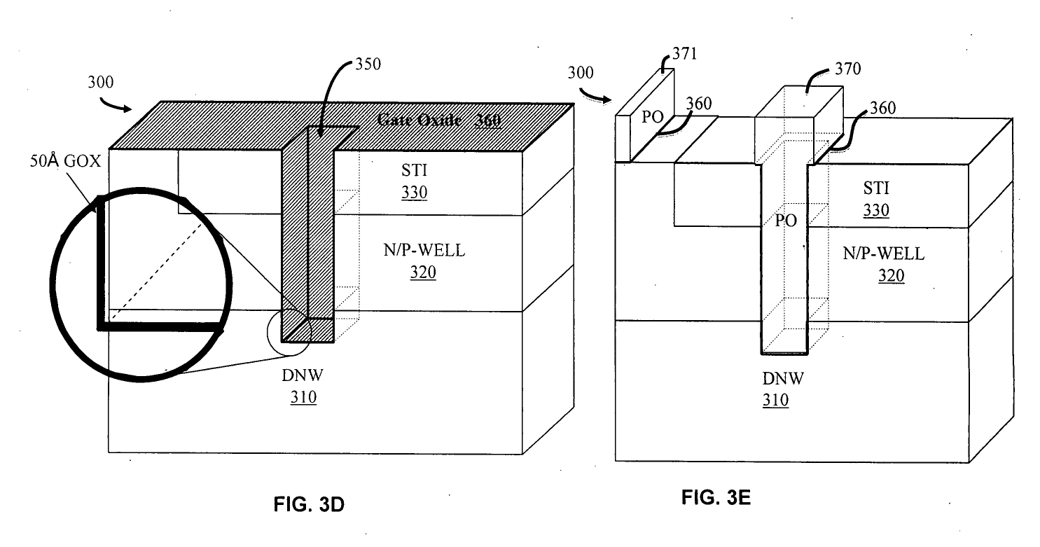

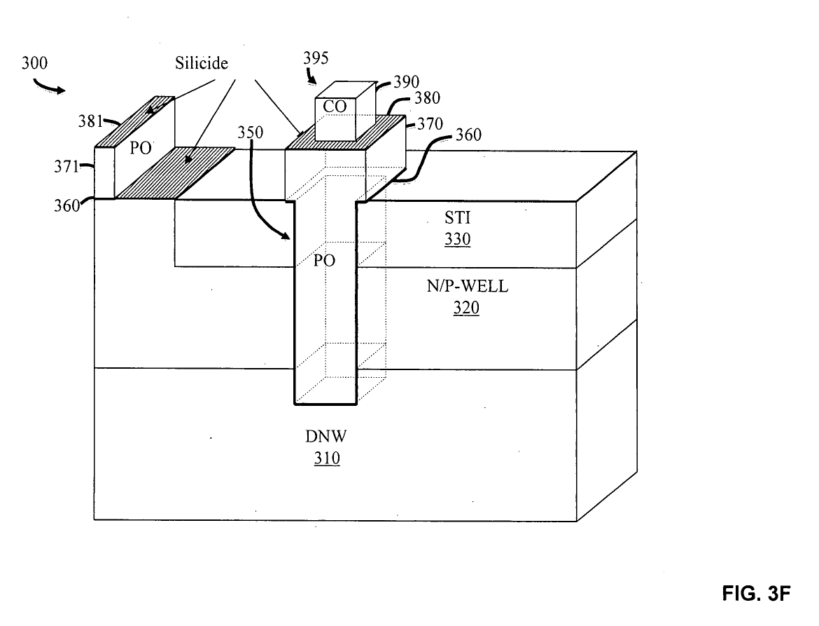

FIGS. 3a-3f illustrate the formation of a deep trench capacitor according to an embodiment of the present invention. FIG. 3a illustrates a semiconductor substrate 300 with a deep N-well (DNW) 310. A regular depth well (N/P-well) 320 resides above the deep N-well 310. The regular depth well 320 may be doped with either N or P dopants. A shallow trench isolation section 330 resides adjacent to and above a portion of the regular depth well 320.

FIG. 3b illustrates the semiconductor substrate 300 after a mask layer 340 is deposited above the STI layer 330 and a portion of the regular depth well 320 and patterned to expose a trench area 341. According to an embodiment of the present invention, a hard mask the may be used to implement the mask layer 340. The hard mask may be formed from Si₃N₄ or other material. The arrows in FIG. 3b represent plasma ions used to etch deep trenches. The hard mask 340 layer blocks the plasma ions from penetrating the STI section 330, regular depth well 320 and deep N-well 310. Plasma ions that travel through the opening of the mask layer 340 etch through the STI section 330, regular depth well 320, and a portion of the deep N-well 310 to create a deep trench 350.

FIG. 3c illustrates the semiconductor substrate 300 after the hard mask 340 (shown in FIG. 3b) is removed. The deep trench 350 is defined by a plurality of walls 351-353 and a floor 354. In FIG. 3c, three of the walls 351-353 are shown. The walls 351-353 span the STI layer 330, regular depth well 320, and deep N-well 310. The floor 354 is on the deep N-well 310

FIG. 3d illustrates the semiconductor substrate 300 with a layer of gate oxide (GOX) 360 grown through out the semiconductor substrate including in the deep trench 350. The gate oxide 360 covers the walls 351-353 and floor 354 (shown in FIG. 3c) of the deep trench 350. The gate oxide in the deep trench 350 is grown at the same time (simultaneously with) and using the same procedure as the gate oxide for a gate of a transistor to be implemented on the semiconductor substrate 300. According to an embodiment of the present invention, the gate oxide is a thick input output (IO) oxide which may be 50 angstroms. The gate oxide layer may be used as the gate dielectric for the transistor. Gate oxide on the surface of the regular depth well 320 and STI 330 and not used for the deep trench capacitor or transistor may be cleaned up.

FIG. 3e illustrates the semiconductor substrate 300 with gate polysilicon (polycrystalline silicon) 371 deposited over the gate oxide of the transistor and gate polysilicon 370 deposited over the gate oxide of the deep trench capacitor. The gate polysilicon 370 and 371 are deposited at the same time using the same deposition procedure. The gate polysilicon may be used as gate electrode material for the metal oxide semiconductor transistor.

FIG. 3f illustrates the semiconductor substrate 300 with a layer of silicide 380 deposited over the gate polysilicon 370 for the deep trench capacitor 395, a layer of silicide 381 deposited over the gate polysilicon 371 for the transistor, a layer of silicide 382 deposited on a portion of the regular depth well 320. According to an embodiment of the present invention, the silicide layers 380, 381, and 382 are deposited at the same time using the same deposition procedure. A contact 390 is formed on top of the silicide layer 380 for the deep trench capacitor 395. The contact 390 allows the gate polysilicon 370 of the deep trench capacitor 395 to be biased in order to better address soft errors. The deep trench capacitor 395 is shown to include a trench 350 having walls and a floor.

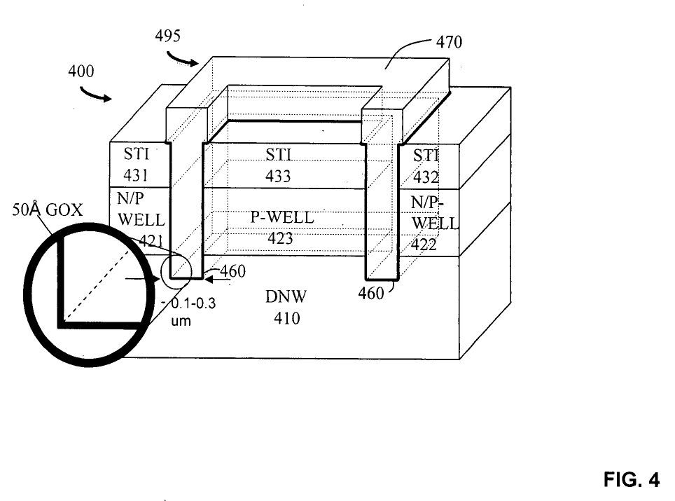

FIG. 4 illustrates an embodiment of a deep trench isolation barrier 495 for deep trench isolation according to an embodiment of the present invention. FIG. 4 illustrates a semiconductor substrate 400 with a deep N-well 410. A plurality of regular depth wells that may be doped with either N or P dopants (N/P-wells) 421 and 422 reside above the deep N-well 410. A regular depth well 423 that is doped with P dopant (P-well) that may be biased at a different voltage than N/P-well also resides above the deep N-well. Shallow trench isolation sections 431-433 reside adjacent to and above the regular depth wells 421-423 respectively. The deep trench isolation barrier 495 is configured with a plurality of walls to surround the P-well 423. Together, the walls of the deep trench capacitor 495 and the deep N-well 410 isolate the P-well 423 from N/P wells 421 and 422.

The deep trench isolation barrier 495 may be fabricated using the procedures illustrated in FIGS. 1, 2, and 3a-e used to fabricate a deep trench isolation capacitor. In this embodiment, a layer of gate oxide 460, and gate polysilicon 470 of the deep trench isolation barrier 495 may be fabricated using procedures for fabricating one or more other components such as transistors on the semiconductor substrate 400. It should further be appreciated that the deep trench isolation barrier 495 may operate as a deep trench capacitor. In this embodiment, silicide and a contact may be added to the deep trench isolation barrier 495.

As described, a deep trench capacitor/deep trench isolation barrier may be fabricated at the same time as transistors or other components for logic gates. The deep trench may be integrated into the fabrication flow just prior to gate oxidation. The deep trench capacitor/deep trench isolation barrier may utilize (“piggy-back” from) the thick gate oxide and gate polysilicon procedures typically used in fabricating transistors. This reduces the overall number of additional procedures required to create the deep trench capacitors/deep trench isolation barrier which results in the conservation of time and other resources. It should be appreciated that the ratio for deep trench (width/depth) may be adjusted as required by process to create a void free trench. Furthermore, by using the deep trench procedure described, the die size of a device may be reduced with the smaller isolation width required for deep trenches.

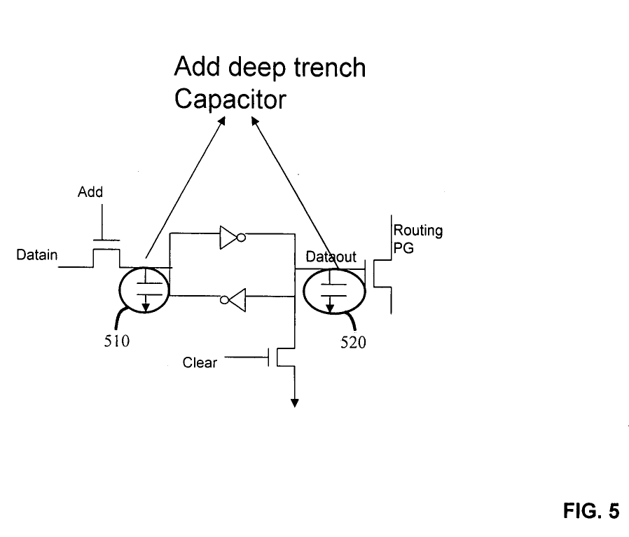

FIG. 5 illustrates a plurality of deep trench capacitors 510 and 520 implemented in a circuit to reduce soft errors according to an embodiment of the present invention. As shown, deep trench capacitors 510 and 520 are implemented in a configurable random access memory (CRAM) to increase node capacitance. By increasing node capacitance, SER concerns may be reduced or mitigated and CRAM scaling may be further explored.

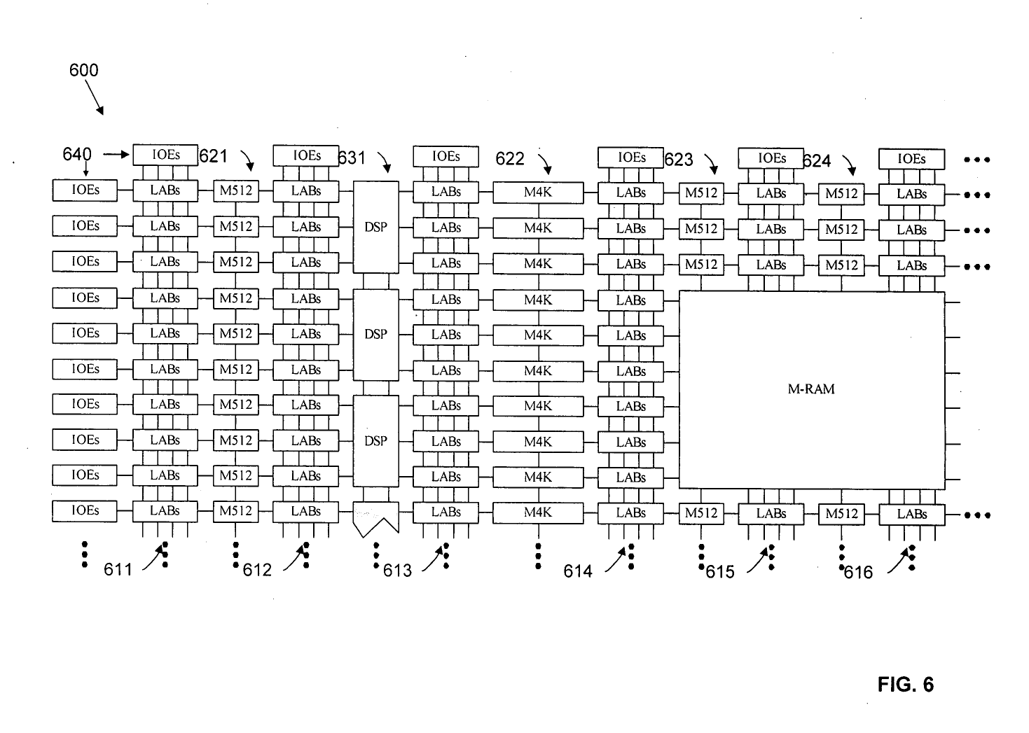

FIG. 6 illustrates a target device where deep trench capacitors are implemented according to embodiments of the present invention. According to one embodiment, the target device 600 is a chip having a hierarchical structure that may take advantage of wiring locality properties of circuits formed therein such as field programmable gate array.

The target device 600 includes a plurality of logic-array blocks (LABs). Each LAB may be formed from a plurality of logic blocks, carry chains, LAB control signals, (lookup table) LUT chain, and register chain connection lines. A logic block is a small unit of logic providing efficient implementation of user logic functions. A logic block includes one or more combinational cells, where each combinational cell has a single output, and registers. Logic blocks may be implemented using CRAMs which are susceptible to SER. According to an embodiment of the present invention, the CRAMs in the LABs include deep trench capacitors which are fabricated with the materials and procedures described with reference to FIGS. 1-5. The LABs are grouped into rows and columns across the target device 600. Columns of LABs are shown as 611-616. It should be appreciated that the logic block may include additional or alternate components.

The target device 600 includes memory blocks. The memory blocks may be, for example, dual port random access memory (RAM) blocks that provide dedicated true dual-port, simple dual-port, or single port memory up to various bits wide at up to various frequencies. The memory blocks may be grouped into columns across the target device in between selected LABs or located individually or in pairs within the target device 600. Columns of memory blocks are shown as 621-624.

The target device 600 includes digital signal processing (DSP) blocks. The DSP blocks may be used to implement multipliers of various configurations with add or subtract features. The DSP blocks include shift registers, multipliers, adders, and accumulators. The DSP blocks may be grouped into columns across the target device 600 and are shown as 631.

The target device 600 includes a plurality of input/output elements (IOEs) 640. Each IOE feeds an I/O pin (not shown) on the target device 600. The IOEs are located at the end of LAB rows and columns around the periphery of the target device 600.

The target device 600 includes LAB local interconnect lines (not shown) that transfer signals between LEs in the same LAB, a plurality of row interconnect lines (“H-type wires”) (not shown) that span fixed distances, and a plurality of column interconnect lines (“V-type wires”) (not shown) that operate similarly to route signals between components in the target device.

FIG. 6 illustrates an exemplary embodiment of a target device. It should be appreciated that a system may include a plurality of target devices, such as that illustrated in FIG. 6, cascaded together. It should also be appreciated that the target device may include programmable logic devices arranged in a manner different than that on the target device 600. A target device may also include FPGA resources other than those described in reference to the target device 600. Thus, while the invention described herein may be utilized on the architecture described in FIG. 6, it should be appreciated that it may also be utilized on different architectures, such as those employed by Altera® Corporation in its APEX™, Stratix™, Cyclone™, Stratix™ II, and Cyclone™ II families of chips and those employed by Xilinx® Inc. in its Virtex™ and Virtex™ II, and Virtex IV™ line of chips.

FIGS. 1 and 2 are flow charts illustrating methods according to embodiments of the present invention. The techniques illustrated in these figures may be performed sequentially, in parallel or in an order other than that which is described. The techniques may be also be performed one or more times. It should be appreciated that not all of the techniques described are required to be performed, that additional techniques may be added, that some of the illustrated techniques may be substituted with other techniques, and that other angles of implantation, dosage of implantation, and other specifics may be utilized to practice the procedures described.

In the foregoing specification embodiments of the invention has been described with reference to specific exemplary embodiments thereof. It will, however, be evident that various modifications and changes may be made thereto without departing from the broader spirit and scope of the embodiments of the invention. The specification and drawings are, accordingly, to be regarded in an illustrative rather than restrictive sense.

What is claimed is:

1. A deep trench capacitor, comprising:
a trench having walls and a floor;
a layer of gate oxide on the walls and the floor; and
gate polysilicon deposited over the gate oxide.

2. The deep trench capacitor of claim 1, wherein the walls defining the trench is etched through a shallow trench isolation (STI) layer, a well doped with one of a P and N ions, and a deep well doped with N ions.

3. The deep trench capacitor of claim 1, wherein the gate oxide of the deep trench capacitor is grown simultaneously with gate oxide for a transistor on a same semiconductor substrate.

4. The deep trench capacitor of claim 1, wherein the gate polysilicon of the deep trench capacitor is deposited simultaneously with gate polysilicon for a transistor on a same semiconductor substrate.

5. The deep trench capacitor of claim 1, further comprising a layer of silicide on top of the gate polysilicon.

6. The deep trench capacitor of claim 4, further comprising a contact on the silicide that is operable to bias the polysilicon

7. The deep trench capacitor of claim 1, wherein the walls and the floor defining the trench extend to surround a P-well to provide isolation.

8. The deep trench capacitor of claim 1, wherein the deep trench capacitor increases node capacitance of a configurable random access memory (CRAM) to reduce soft error rate (SER).

9. A deep trench capacitor prepared by a process, the process comprising:
creating a deep trench; and
growing gate oxide in the deep trench and depositing polysilicon in the deep trench while forming a transistor.

10. The product by process of claim 9, further comprising depositing silicide on the polysilicon.

11. The product by process of claim 10, wherein the silicide is deposited while depositing silicide to form the transistor.

12. The product by process of claim 9, further comprising forming a contact operable to bias the polysilicon.

13. The product by process of claim 9, wherein creating the deep trench comprises:
depositing a hard mask;
patterning an area for an opening of the deep trench; and
performing plasma etching.

14. The product by process of claim 9, wherein the plasma etching penetrates a shallow trench isolation (STI) layer, a well doped with one of a P and N ions, and a deep well doped with N ions.

15. A method for isolating a well doped with a first type of dopants, comprising:
creating a deep trench around the well;
growing gate oxide in the deep trench while forming a transistor; and
depositing polysilicon in the deep trench while forming the transistor.

16. The method of claim 15, further comprising depositing silicide on the polysilicon.

17. The method of claim 16, wherein the silicide is deposited while depositing silicide to form the transistor.

18. The method of claim 15, further comprising forming a contact operable to bias the polysilicon.

19. The method of claim 15, wherein creating the deep trench comprises:
depositing a hard mask;
patterning an area for an opening of the deep trench; and
performing plasma etching.

20. The method of claim 15, wherein the plasma etching penetrates a shallow trench isolation (STI) layer, a well doped with one of a P and N ions, and a deep well doped with N ions.

21. An isolation barrier formed from the process of claim 15.

22. A deep trench capacitor prepared by a process, the process comprising:
growing gate oxide in a deep trench and depositing polysilicon in the deep trench while forming a transistor; and
depositing silicide on the polysilicon.

23. The product by process of claim 22, wherein the silicide is deposited while depositing silicide to form the transistor.

24. The product by process of claim 22, further comprising forming a contact operable to bias the polysilicon.
